(19) United States
(12) Patent Application Publication
(10) Pub. No.: US 2023/0006069 A1
(43) Pub. Date: Jan. 5, 2023

(54) MANUFACTURING METHOD OF SEMICONDUCTOR STRUCTURE AND SEMICONDUCTOR STRUCTURE

(71) Applicant: CHANGXIN MEMORY TECHNOLOGIES, INC., Hefei City (CN)

(72) Inventor: Shang GAO, Hefei City (CN)

(21) Appl. No.: 17/648,566

(22) Filed: Jan. 21, 2022

Related U.S. Application Data
(63) Continuation of application No. PCT/CN2021/120113, filed on Sep. 24, 2021.

(30) Foreign Application Priority Data
Jul. 5, 2021 (CN) 202110757717.0

(51) Int. Cl. H01L 29/786; H01L 29/66

(52) U.S. Cl. CPC H01L 29/78672; H01L 29/7869; H01L 29/6675

(57) ABSTRACT

The present disclosure provides a method of manufacturing a semiconductor structure and a semiconductor structure. The method of manufacturing a semiconductor structure includes: providing an intermediate semiconductor structure; etching a part of the mandrel layer, exposing a part of the polycrystalline silicon layer, and forming a first spacing group; depositing a first spacing layer, and covering the first spacing group and an exposed area of the polycrystalline silicon layer; removing the first spacing group and a part of the first spacing layer, exposing a part of the polycrystalline silicon layer, and forming a second spacing group; depositing a second spacing layer, and covering the second spacing group and an exposed area of the polycrystalline silicon layer; removing the second spacing group and a part of the second spacing layer, exposing a part of the polycrystalline silicon layer, and forming a third spacing group.

### CROSS-REFERENCE TO RELATED APPLICATIONS

This is a continuation of International Application No. PCT/CN2021/120113, filed on Sep. 24, 2021, which claims the priority to Chinese Patent Application No. 202110757717.0, titled “MANUFACTURING METHOD OF SEMICONDUCTOR STRUCTURE AND SEMICONDUCTOR STRUCTURE” and filed with the China National Intellectual Property Administration (CNIPA) on Jul. 5, 2021. The entire contents of International Application No. PCT/CN2021/120113 and Chinese Patent Application No. 202110757717.0 are incorporated herein by reference.

### TECHNICAL FIELD

The present disclosure relates to, but is not limited to, a method of manufacturing a semiconductor structure and a semiconductor structure.

### BACKGROUND

As integration degrees of semiconductor devices become higher, critical dimensions and distances of patterns gradually shrink. In the traditional process, two layers of mandrels need to be disposed and are subjected to etching for multiple times, resulting in cumbersome process steps. At the same time, multiple etching processes easily change a distance between transferred patterns, resulting in poor quality of a transferred pattern.

### SUMMARY

An overview of the subject matter detailed in the present disclosure is provided below, which is not intended to limit the protection scope of the claims.

The present disclosure provides a method of manufacturing a semiconductor structure and a semiconductor structure.

According to a first aspect, the present disclosure provides a method of manufacturing a semiconductor structure. The method of manufacturing a semiconductor structure includes:

providing an intermediate semiconductor structure, wherein the intermediate semiconductor structure includes a substrate, and an oxide layer, a polycrystalline silicon layer, and a mandrel layer that are sequentially stacked on the substrate;

etching a part of the mandrel layer, exposing a part of the polycrystalline silicon layer, and forming a first spacing group;

depositing a first spacing layer, and covering the first spacing group and an exposed area of the polycrystalline silicon layer;

removing the first spacing group and a part of the first spacing layer, exposing a part of the polycrystalline silicon layer, and forming a second spacing group;

depositing a second spacing layer, and covering the second spacing group and an exposed area of the polycrystalline silicon layer;

removing the second spacing group and a part of the second spacing layer, exposing a part of the polycrystalline silicon layer, and forming a third spacing group; and

removing a part of the polycrystalline silicon layer and the third spacing group, and forming a fourth spacing group, wherein the fourth spacing group exposes a part of the oxide layer.

According to a second aspect, the present disclosure provides a semiconductor structure. The semiconductor structure includes:

a substrate; and

an oxide layer, disposed on the substrate; and

a polycrystalline silicon layer, disposed on the oxide layer, wherein the polycrystalline silicon layer includes multiple spacing units disposed at intervals, two adjacent spacing units form a groove, and the groove exposes a part of the oxide layer; wherein

the polycrystalline silicon layer is processed by using the method of manufacturing a semiconductor structure according to the first aspect.

Other aspects are understandable upon reading and understanding of the accompanying drawings and detailed description.

### BRIEF DESCRIPTION OF THE DRAWINGS

The drawings incorporated into the specification and constituting a part of the specification illustrate the embodiments of the present application, and are used together with the description to explain the principles of the embodiments of the present disclosure. In these accompanying drawings, similar reference numerals are used to represent similar elements. The accompanying drawings in the following description are part rather than all of the embodiments of the present disclosure. Those skilled in the art may derive other drawings based on these drawings without creative efforts.

FIG. 1 is a flowchart of a method of manufacturing a semiconductor structure according to an exemplary embodiment;

FIG. 2 is a flowchart of a method of manufacturing a semiconductor structure according to an exemplary embodiment;

FIG. 3 is a schematic diagram of an intermediate semiconductor structure in the method of manufacturing a semiconductor structure shown in FIG. 1;

FIG. 4 is a schematic diagram of a structure obtained after implementing step S202 of the method of manufacturing a semiconductor structure shown in FIG. 2;

FIG. 5 is a schematic diagram of a structure obtained after implementing step S204 of the method of manufacturing a semiconductor structure shown in FIG. 2;

FIG. 6 is a schematic diagram of a structure obtained after implementing step S206 of the method of manufacturing a semiconductor structure shown in FIG. 2;

FIG. 7 to FIG. 9 are schematic diagrams of structures involved in a process of step S208 of the method of manufacturing a semiconductor structure shown in FIG. 2;

FIG. 10 is a schematic diagram of a structure obtained after implementing step S210 of the method of manufacturing a semiconductor structure shown in FIG. 2;

FIG. 11 to FIG. 13 are schematic diagrams of structures involved in a process of step S212 of the method of manufacturing a semiconductor structure shown in FIG. 2;

FIG. 14 is a schematic diagram of a structure involved in a process of step S214 of the method of manufacturing a semiconductor structure shown in FIG. 2; and

FIG. 15 is a schematic diagram of a semiconductor structure according to an exemplary embodiment.

### DETAILED DESCRIPTION

The technical solutions in the embodiments of the present disclosure are described below clearly and completely with reference to the drawings in the embodiments of the present disclosure. Apparently, the described embodiments are merely part rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

Specific implementations of a method of manufacturing a semiconductor structure and a semiconductor structure provided in the present disclosure are described below in detail with reference to the accompanying drawings.

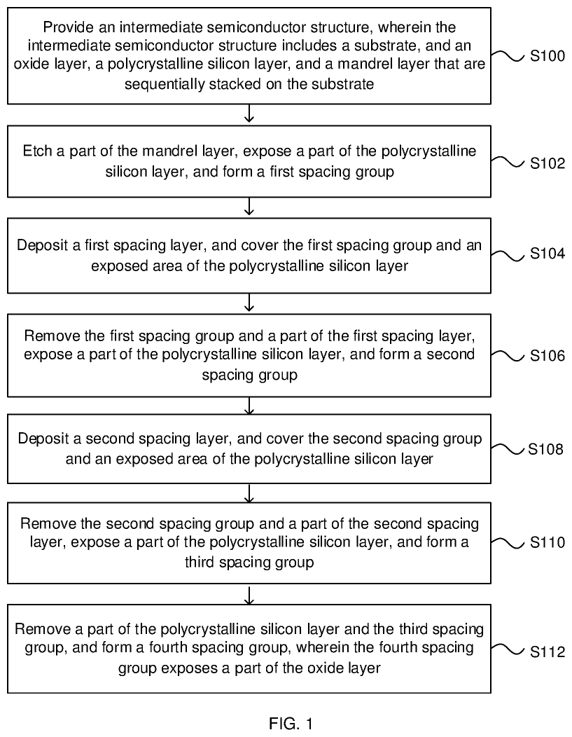

As shown in FIG. 1, a method of manufacturing a semiconductor structure provided in an embodiment of the present disclosure includes:

Step S100: Provide an intermediate semiconductor structure, wherein the intermediate semiconductor structure includes a substrate, and an oxide layer, a polycrystalline silicon layer, and a mandrel layer that are sequentially stacked on the substrate.

Step S102: Etch a part of the mandrel layer, expose a part of the polycrystalline silicon layer, and form a first spacing group.

Step S104: Deposit a first spacing layer, and cover the first spacing group and an exposed area of the polycrystalline silicon layer.

Step S106: Remove the first spacing group and a part of the first spacing layer, expose a part of the polycrystalline silicon layer, and form a second spacing group.

Step S108: Deposit a second spacing layer, and cover the second spacing group and an exposed area of the polycrystalline silicon layer.

Step S110: Remove the second spacing group and a part of the second spacing layer, expose a part of the polycrystalline silicon layer, and form a third spacing group.

Step S112: Remove a part of the polycrystalline silicon layer and the third spacing group, and form a fourth spacing group, wherein the fourth spacing group exposes a part of the oxide layer.

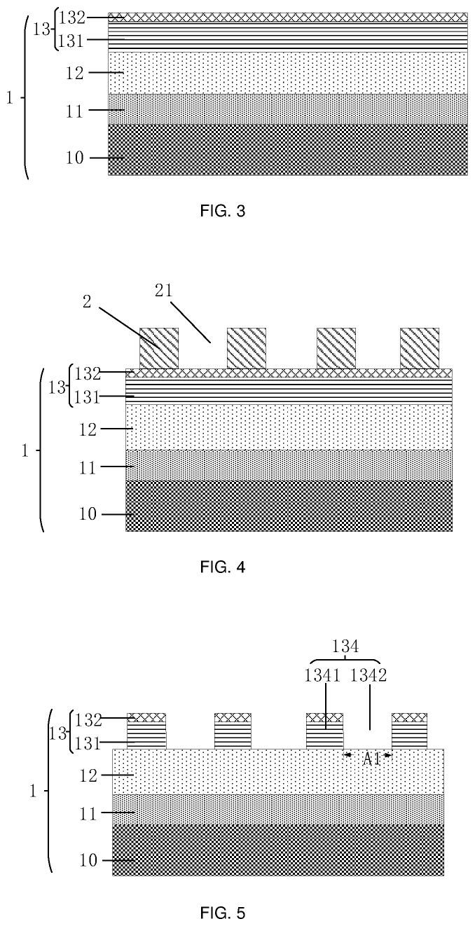

In step S100, referring to FIG. 3, an intermediate semiconductor structure 1 is provided. The intermediate semiconductor structure 1 includes a substrate 10 and a laminated structure formed above the substrate 10. The laminated structure includes an oxide layer 11, a polycrystalline silicon layer 12, and a mandrel layer 13 that are sequentially stacked in a direction away from the substrate 10.

The substrate 10 may be made of monocrystalline silicon, polycrystalline silicon, amorphous silicon, silicon-germanium compound, silicon-on-insulator (SOI), or the like. The polycrystalline silicon layer 12 has an advantage of easily implementing a self-aligned process, and a pattern obtained after etching has a better vertical characteristic. The mandrel layer 13 may also include multiple film layers. The mandrel layer 13 may include, for example, one or any combination of a polycrystalline silicon layer, a silicon oxide layer, a silicon nitride layer, an amorphous carbon layer, and a silicon oxynitride layer.

In this embodiment, the mandrel layer 13 includes a silicon oxynitride (SiON) layer 132 and a spin-on-hardmask (SOH) layer 131 that are stacked. Referring to FIG. 3, along the direction away from the substrate 10, the spin-on-hardmask layer 131 and the silicon oxynitride layer 132 that are stacked are sequentially provided above the polycrystalline silicon layer 12, that is, the silicon oxynitride layer 132 is located above the spin-on-hardmask layer 131. For example, the spin-on-hardmask layer 131 and the silicon oxynitride layer 132 may be sequentially deposited above the polycrystalline silicon layer 12 through a chemical vapor deposition process, so that thicknesses of formed films of the spin-on-hardmask layer 131 and the silicon oxynitride layer 132 can be precisely controlled.

In step S102, referring to FIG. 3, the mandrel layer 13 continuously covers above the polycrystalline silicon layer 12. When the mandrel layer 13 is etched, a part of area of the mandrel layer 13 may be etched through a photolithography process. As shown in FIG. 5, an area of the mandrel layer 13 that is etched forms a second groove 1342. The second groove 1342 exposes a part of the surface of the polycrystalline silicon layer 12, and the second groove 1342 separates the remaining part of the mandrel layer 13 to form a first spacing group 134. Because the silicon oxynitride layer 132 is easy to etch, the difficulty of an etching process during the process of etching the mandrel layer 13 can be effectively reduced.

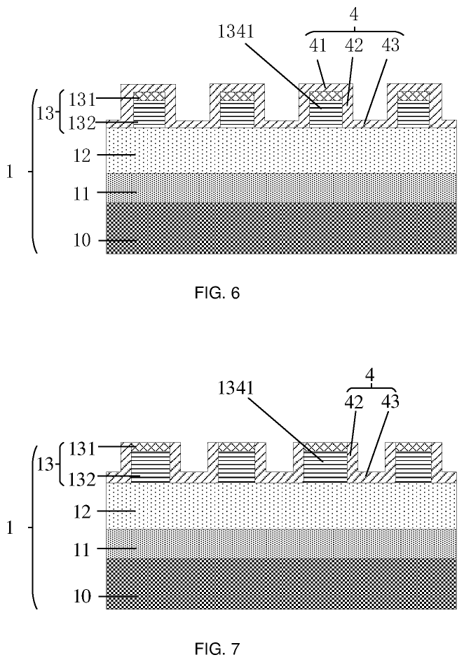

In step S104, referring to FIG. 5 and FIG. 6, after the first spacing group 134 is formed, a first spacing layer 4 is deposited on the surface of the reserved mandrel layer 13 and the surface of the exposed polycrystalline silicon layer 12, so that the first spacing layer 4 covers the outer surface of the first spacing group 134 and covers the exposed surface of the polycrystalline silicon layer 12. When the first spacing layer 4 is deposited, for example, chemical vapor deposition (CVD), atomic layer deposition (ALD), or physical vapor deposition (PVD) may be used.

In step S106, referring to FIG. 6 and FIG. 9, after the first spacing group 134 is removed through the etching process, the first spacing layer 4 is etched, and a reserved part of the first spacing layer 4 forms a second spacing group 44. The second spacing group 44 forms multiple third grooves 442. The third groove 442 exposes a part of the surface of the polycrystalline silicon layer 12, and the third groove 442 separates the remaining part of the first spacing layer 4 to form the second spacing group 44.

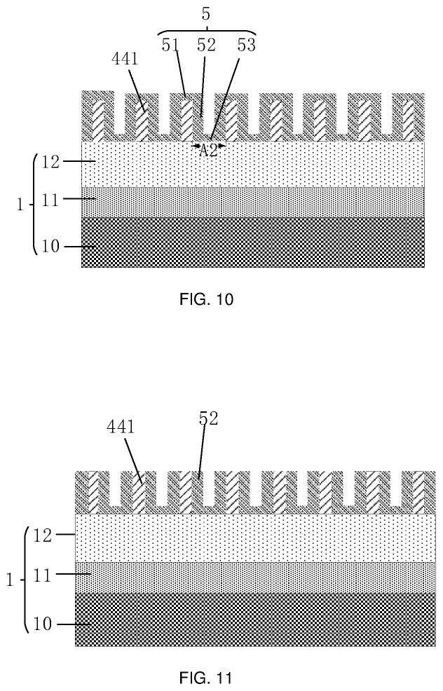

In step S108, referring to FIG. 10, after the second spacing group 44 is formed, a second spacing layer 5 is deposited, and the second spacing layer 5 covers the exposed outer surface of the second spacing group 44 and an exposed part of the surface of the polycrystalline silicon layer 12.

In step S110, referring to FIG. 10 and FIG. 13, a part of the second spacing layer 5 covering the second spacing group 44 is removed to expose a part of the surface of the remaining first spacing layer 4. The remaining first spacing layer 4 is entirely removed, that is, the second spacing group 44 is removed. Then, fourth grooves 542 are formed between some structures of the remaining second spacing layer 5. The fourth groove 542 exposes a part of the surface of the polycrystalline silicon layer 12, and the fourth groove 542 separates the remaining second spacing layer 5 to form a third spacing group 54.

In step S112, referring to FIG. 13 and FIG. 15, after the third spacing group 54 is formed, a shape defined by the third spacing group 54 is used as a mask pattern. According to the mask pattern, the exposed surface of the polycrystalline silicon layer 12 is etched downwards. A fifth groove 1212 is formed on the polycrystalline silicon layer 12, and the fifth groove 1212 exposes a part of the surface of the oxide layer 11. A part of the polycrystalline silicon layer 12 is reserved, and the reserved polycrystalline silicon layer 12 is separated by the fifth groove 1212 to form a fourth spacing group 121. At the same time, before the fourth spacing group 121 is formed, the third spacing group 54 needs to be removed.

This embodiment of the present disclosure provides a method of manufacturing a semiconductor structure. The mandrel layer is deposited above the substrate, a part of the mandrel layer is removed, the first spacing layer is deposited on the remaining part of the mandrel layer, the mandrel layer and a part of the first spacing layer are removed, the remaining part of the first spacing layer is reserved as the first spacing group, the second spacing layer is deposited on the first spacing group, the first spacing group and a part of the second spacing layer are removed, the remaining part of the second spacing layer is reserved as the third spacing group, and the polycrystalline silicon layer is etched by using the third spacing group as the mask. In the method of manufacturing a semiconductor structure provided by the present disclosure, only the mandrel layer is etched, which effectively reduces processing steps, reduces the impact of the etching process on a feature size of a transferred pattern, avoids the problem of pitch variation, and improves the processing efficiency while ensuring the processing effect.

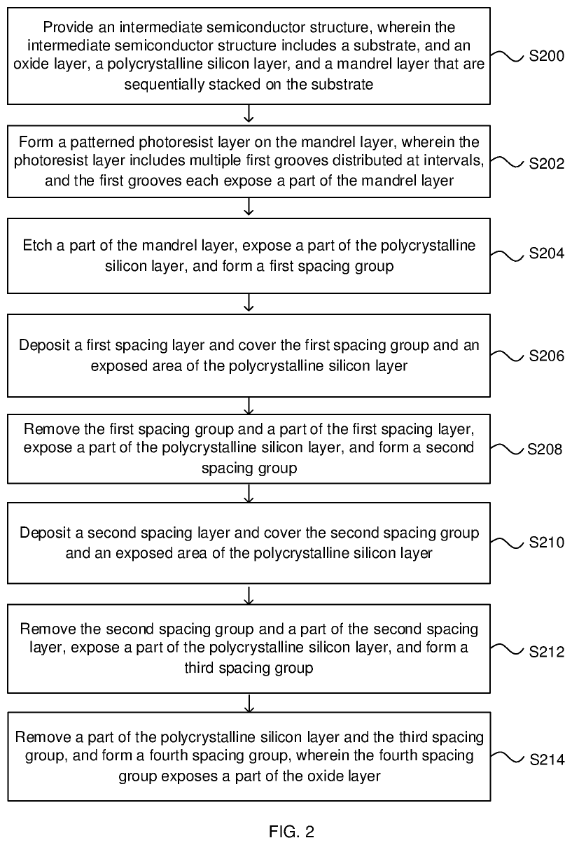

With reference to FIG. 2, an exemplary embodiment provides a method of manufacturing a semiconductor structure. The method of manufacturing a semiconductor structure includes:

Step S200: Provide an intermediate semiconductor structure, wherein the intermediate semiconductor structure includes a substrate, and an oxide layer, a polycrystalline silicon layer, and a mandrel layer that are sequentially stacked on the substrate.

Step S202: Form a patterned photoresist layer on the mandrel layer, wherein the photoresist layer includes multiple first grooves distributed at intervals, and the first grooves each expose a part of the mandrel layer.

Step S204: Etch a part of the mandrel layer, expose a part of the polycrystalline silicon layer, and form a first spacing group.

Step S206: Deposit a first spacing layer, and cover the first spacing group and an exposed area of the polycrystalline silicon layer.

Step S208: Remove the first spacing group and a part of the first spacing layer, expose a part of the polycrystalline silicon layer, and form a second spacing group.

Step S210: Deposit a second spacing layer to cover the second spacing group and an exposed area of the polycrystalline silicon layer.

Step S212: Remove the second spacing group and a part of the second spacing layer, expose a part of the polycrystalline silicon layer, and form a third spacing group.

Step S214: Remove a part of the polycrystalline silicon layer and the third spacing group, and form a fourth spacing group, wherein the fourth spacing group exposes a part of the oxide layer.

In this embodiment, the implementation of step S200 is the same as the implementation of the foregoing embodiment, and details are not described herein again.

In step S202 of this embodiment, referring to FIG. 4, a patterned photoresist layer 2 is formed on the surface of the mandrel layer 13. The patterned photoresist layer 2 has a first groove 21, and multiple first grooves 21 are distributed at intervals in a direction parallel with the substrate 10. A position corresponding to the first groove 21 exposes a part of the surface of the mandrel layer 13, so that a part of the structure of the mandrel layer 13 may be etched through the first groove 21. In this embodiment, a pattern is transferred to the mandrel layer 13 through the patterned photoresist layer 2, thereby selectively etching the mandrel layer 13. The outer circumference of the first groove 21 is perpendicular to the surface of the mandrel layer 13, and the longitudinal cross section of the first groove 21 includes, but is not limited to, a rectangle. Exemplarily, a number of first grooves 21 is 3. In other exemplary embodiments, the number of first grooves 21 may be 1, 2, 4, or the like, and is not specifically limited herein.

In this embodiment, the photoresist layer 2 may be exposed through partial exposure, a part of the photoresist layer 2 is removed after development, and the remaining part of the photoresist layer 2 forms the patterned photoresist layer 2. The photoresist layer 2 may be a negative photoresist layer or a positive photoresist layer. Partial exposure may be implemented, for example, by shielding with a light shield.

In this embodiment, the process of etching a part of the mandrel layer, exposing a part of the polycrystalline silicon layer, and forming a first spacing group in step S204 may include:

etching a part of the mandrel layer by using the photoresist layer as a mask layer, and forming a second groove, wherein the second groove exposes a first area of the polycrystalline silicon layer, and a reserved part of the mandrel layer forms the first spacing group.

The first spacing group includes multiple spaced first spacing units perpendicular to the polycrystalline silicon layer.

Referring to FIG. 4 and FIG. 5, the patterned photoresist layer 2 is used as a mask layer, and a part of the mandrel layer 13 may be etched vertically downwards at the first groove 21 in a direction perpendicular to the surface of the substrate 10 through a photolithography process, until the surface of the polycrystalline silicon layer 12 is exposed. A position where a part of the mandrel layer 13 is removed correspondingly forms a second groove 1342, and the position corresponding to the second groove 1342 exposes a part of the surface of the polycrystalline silicon layer 12. The remaining part of the mandrel layer 13 is separated by second grooves 1342 to form first spacing units 1341, the first spacing units 1341 disposed at intervals form a first spacing group 134, and the second groove 1342 is located between adjacent first spacing units 1341. The sidewall surface of the second groove 1342 coincides with the sidewall surface of the first spacing unit 1341, and the sidewall surface of the first spacing unit 1341 is perpendicular to the surface of the polycrystalline silicon layer 12. This facilitates transfer of a pattern of the photoresist layer 2 to the mandrel layer 13 through the etching process, and the mandrel layer 13 is used to form the first spacing group 134. Exemplarily, referring to FIG. 5, a number of second grooves 1342 is 3, and a number of first spacing units 1341 is 4.

In this embodiment, before the first spacing layer is deposited in step S206, the patterned photoresist layer used as the mask layer is removed.

Referring to FIG. 4 and FIG. 5, since the photoresist layer 2 used as the mask layer is no longer needed, the photoresist layer 2 needs to be completely removed from the surface of the mandrel layer 13. For example, the photoresist layer 2 may be removed through a wet chemical process.

In this embodiment, the process of depositing a first spacing layer, and covering the first spacing group and an exposed area of the polycrystalline silicon layer in step S206 may include:

depositing the first spacing layer through a physical vapor deposition process, wherein the first spacing layer covers a top surface and sidewall surfaces of each of the first spacing units and the first area of the polycrystalline silicon layer.

In this embodiment, referring to FIG. 5 and FIG. 6, since the first spacing group 134 is formed by four first spacing units 1341 disposed at intervals, the deposited first spacing layer 4 is formed conformally on the surface of the first spacing units 1341. For example, the first spacing layer 4 covers the side walls and tops of the first spacing units 1341, and the first spacing layer 4 may also cover only the side walls of the first spacing units 1341. This is not limited herein and may be adjusted according to the actual process. Since a part of area of the polycrystalline silicon layer 12 is exposed between adjacent first spacing units 1341, the first spacing layer 4 also covers an exposed first area A1 of the polycrystalline silicon layer 12. In this implementation, the first spacing layer 4 with the best hardness can be formed through the physical vapor deposition process, which can effectively prevent the first spacing layer 4 from being deformed by the etching process and help to evenly transfer a pattern downwards.

In this embodiment, the material of the first spacing layer includes titanium nitride. Titanium nitride has good step coverage, which helps to completely cover the first spacing group, and the thickness of the first spacing layer is easy to control. In addition, high hardness of titanium nitride helps to form a square structure with good verticality, which in turn facilitates downward transfer of a pattern. When the first spacing layer is deposited, for example, chemical vapor deposition (CVD) or atomic layer deposition (ALD) may be used.

In this embodiment, the first spacing layer may also be manufactured with a material that satisfies that a Young's modulus is greater than 200 Gpa, wherein the Young's modulus is an elastic modulus along the longitudinal direction. According to Hooke's law, within the elastic limit of an object, the stress is directly proportional to the strain, and the ratio is called a Young's modulus of the material. The Young's modulus is a physical quantity that represents the property of a material and depends only on the physical property of the material itself. The magnitude of the Young's modulus marks the rigidity of a material, and the higher Young's modulus indicates being less likely to be deformed and being easier to form a structure with better verticality, which facilitates downward transfer of a pattern.

In this embodiment, the process of removing the first spacing group and a part of the first spacing layer, exposing a part of the polycrystalline silicon layer, and forming a second spacing group in step S208 may include:

etching a part of the first spacing layer covering the top surface of each of the first spacing units;

etching a part of the first spacing layer covering the first area of the polycrystalline silicon layer; and

removing the first spacing group, wherein a reserved part of the first spacing layer forms the second spacing group;

wherein the second spacing group includes multiple spaced second spacing units perpendicular to the polycrystalline silicon layer, two adjacent second spacing units form a third groove, and the third groove exposes a second area of the polycrystalline silicon layer.

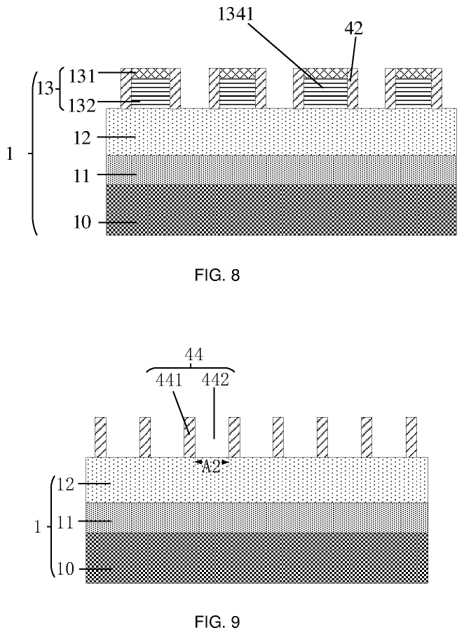

FIG. 6 shows the first spacing layer formed on the first spacing group and the exposed area of the polycrystalline silicon layer, wherein the first spacing layer 4 may include a top first spacing layer 41, a middle first spacing layer 42, and a bottom first spacing layer 43. The top first spacing layer 41 is located on the top surface of the first spacing unit 1341, the middle first spacing layer 42 is located on the sidewall surface of the first spacing unit 1341, and the bottom first spacing layer 43 is located on the first area A1 of the polycrystalline silicon layer 12. In this embodiment, referring to FIG. 6 and FIG. 7, for example, the top first spacing layer 41 and a part of the bottom first spacing layer 43 may be etched from top to bottom through a photolithography process, and the middle first spacing layer 42 is reserved. Referring to FIG. 7, after the top first spacing layer 41 is etched, the top surface of the first spacing unit 1341 is exposed. Exemplarily, the top surface of the reserved middle first spacing layer 42 is flush with the top surface of the first spacing unit 1341. Based on the circumference of the top surface of the first spacing unit 1341, the first spacing unit 1341 is vertically etched downwards in a direction perpendicular to the surface of the polycrystalline silicon layer 12. Referring to FIG. 8 and FIG. 9, after the first spacing unit 1341 is removed, only the middle first spacing layer 42 remains on the surface of the polycrystalline silicon layer 12. A third groove 442 is formed between adjacent middle first spacing layers 42 at a position where the first spacing unit 1341 is removed. A position corresponding to the third groove 442 exposes a second area A2 of the polycrystalline silicon layer 12, and the middle first spacing layer 42 forms a second spacing unit 441. Second spacing units 441 distributed at intervals form a second spacing group 44, and the sidewall surface of the second spacing unit 441 coincides with the sidewall surface of the third groove 442. Therefore, the sidewall surface of the second spacing unit 441 is perpendicular to the surface of the polycrystalline silicon layer 12. Exemplarily, referring to FIG. 9, a number of third grooves 442 in the second spacing group 44 is 7, a number of second spacing units 441 is 8, and the second spacing unit 441 includes, but is not limited to, a square structure.

In this embodiment, a width of a projected profile of the first spacing unit on the substrate is greater than a width of a projected profile of the second spacing unit on the substrate. Referring to FIG. 5 and FIG. 9, a width of a longitudinal cross section of a projected outer profile of the outer circumference of the first spacing unit 1341 on the surface of the substrate 1 is greater than a width of a longitudinal cross section of a projected outer profile of the outer circumference of the second spacing unit 441 on the surface of the substrate 1.

In this embodiment, a number of the second spacing units is twice a number of the first spacing units. Referring to FIG. 5 and FIG. 9, four first spacing units 1341 are formed on the mandrel layer 13 by using the photoresist layer 2 as a mask layer, and eight second spacing units 441 are formed through the remaining part of the first spacing layer 4. Therefore, the number of the second spacing units 441 is twice the number of the first spacing units 1341.

In this embodiment, the process of depositing a second spacing layer and covering the second spacing group and an exposed area of the polycrystalline silicon layer in step S210 may include:

depositing the second spacing layer through an atomic layer deposition process, wherein the second spacing layer covers a top surface and sidewall surfaces of each of the second spacing units and the second area of the polycrystalline silicon layer.

Referring to FIG. 9 and FIG. 10, since the second spacing group 44 is formed by eight second spacing units 441 disposed at intervals, the deposited second spacing layer 5 is conformally formed on the surface of the second spacing units 441. For example, the second spacing layer 5 covers the side walls and tops of the second spacing units 441, and the second spacing layer 5 may also cover only the side walls of the second spacing units 441. This is not limited herein and may be adjusted according to the actual process. Since a part of area of the polycrystalline silicon layer 12 is exposed between adjacent second spacing units 441, the second spacing layer 5 also covers the exposed first area A2 of the polycrystalline silicon layer 12.

In this embodiment, a material of the first spacing layer is the same as or different from a material of the second spacing layer. Since non-metal oxide has better coverage performance, non-metal oxide can be selected as the material of the second spacing layer, so that a uniform line width can be obtained on the surface of the polycrystalline silicon layer. Exemplarily, a material of the second spacing layer includes, but is not limited to, silicon oxide or silicon oxynitride. When the second spacing layer is deposited, for example, chemical vapor deposition (CVD) or physical vapor deposition (PVD) may be used.

In this embodiment, the process of removing the second spacing group and a part of the second spacing layer, exposing a part of the polycrystalline silicon layer, and forming a third spacing group in step S212 may include:

etching a part of the second spacing layer covering the top surface of each of the second spacing units;

etching a part of the second spacing layer covering the second area of the polycrystalline silicon layer; and

removing the second spacing group, wherein a reserved part of the second spacing layer forms the third spacing group;

wherein the third spacing group includes multiple spaced third spacing units perpendicular to the polycrystalline silicon layer, two adjacent third spacing units form a fourth groove, and the fourth groove exposes a third area of the polycrystalline silicon layer.

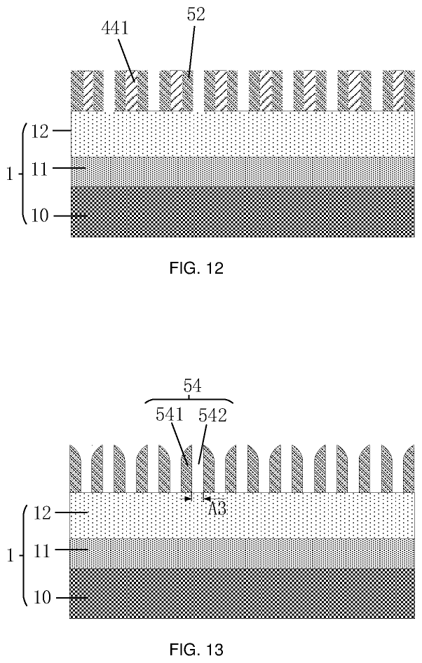

FIG. 10 shows the second spacing layer formed on the second spacing group and the exposed area of the polycrystalline silicon layer, wherein the second spacing layer 5 includes a top second spacing layer 51, a middle second spacing layer 52, and a bottom second spacing layer 53. The top second spacing layer 51 is located on the top surface of the second spacing unit 441, the middle second spacing layer 52 is located on the sidewall surface of the second spacing unit 441, and the bottom second spacing layer 53 is located on the second area A2 of the polycrystalline silicon layer 12. In this embodiment, referring to FIG. 11 and FIG. 12, for example, the top second spacing layer 51 and a part of the bottom second spacing layer 53 may be etched from top to bottom through a photolithography process, and the middle second spacing layer 52 is reserved. Referring to FIG. 11, after the top second spacing layer 51 is etched, the top surface of the second spacing unit 441 is exposed. The top surface of the reserved middle second spacing layer 52 is flush with the top surface of the second spacing unit 441. Based on the circumference of the top surface of the second spacing unit 441, the second spacing unit 441 is vertically etched downwards in a direction perpendicular to the surface of the polycrystalline silicon layer 12. Referring to FIG. 12 and FIG. 13, after the second spacing unit 441 is removed, only the middle second spacing layer 52 remains on the surface of the polycrystalline silicon layer 12. A fourth groove 542 is formed between adjacent middle second spacing layers 52 at a position where the second spacing unit 441 is removed. A position corresponding to the fourth groove 542 exposes a third area A3 of the polycrystalline silicon layer 12, and the middle second spacing layer 52 forms a third spacing unit 541. Third spacing units 541 distributed at intervals form a third spacing group 54, and the sidewall surface of the third spacing unit 541 coincides with the sidewall surface of the fourth groove 542. Therefore, the sidewall surface of the third spacing unit 541 is perpendicular to the surface of the polycrystalline silicon layer 12. Exemplarily, referring to FIG. 13, a number of fourth grooves 542 in the third spacing group 54 is 15, and a number of third spacing units 541 is 16. Referring to FIG. 4 and FIG. 13, 4 first spacing units 1341 are formed on the mandrel layer 13 by using the photoresist layer 2 as a mask layer, and 16 third spacing units 541 are formed through the remaining part of the second spacing layer 5. Therefore, the number of the third spacing units 541 is quadruple the number of the first spacing units 1341.

The third spacing unit 541 is formed by the remaining second spacing layer 5. When the material of the second spacing layer 5 is non-metal oxide, due to insufficient Mohs hardness of the material, exemplarily, the upper part of the third spacing unit 541 forms a circular structure during the etching process, as shown in FIG. 13. When the Mohs hardness of the second spacing layer 5 is greater than or equal to 8 or 9, the upper part of the third spacing unit 541 may form a square structure.

In this embodiment, the process of removing a part of the polycrystalline silicon layer and the third spacing group, and forming a fourth spacing group, wherein the fourth spacing group exposes a part of the oxide layer in step S214 may include:

etching the third area of the polycrystalline silicon layer, and forming a fifth groove, wherein a reserved part of the polycrystalline silicon layer forms the fourth spacing group; and

removing the third spacing group;

wherein the fourth spacing group includes multiple spaced fourth spacing units perpendicular to the oxide layer, two adjacent fourth spacing units form the fifth groove, and the fifth groove exposes a part of the oxide layer.

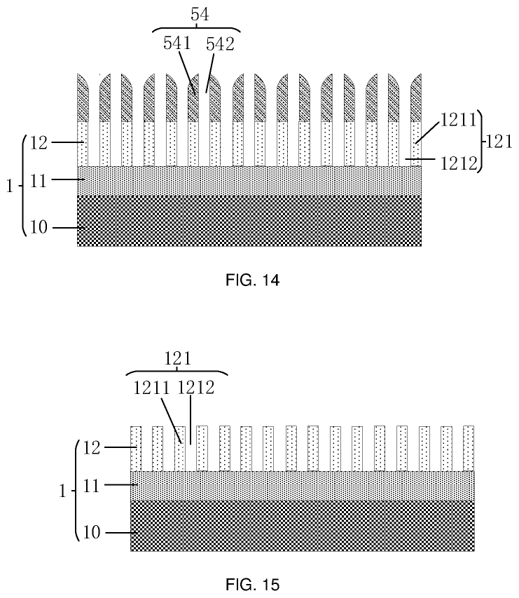

Referring to FIG. 13 and FIG. 14, the fourth groove 542 exposes the third area A3 of the polycrystalline silicon layer 12. The third spacing group 54 is used as a mask layer. Based on the circumference of the third area A3, a part of the polycrystalline silicon layer 12 may be vertically etched downwards in a direction perpendicular to the surface of the oxide layer 11 through a photolithography process. A fifth groove 1212 is correspondingly formed at a position where the part of the polycrystalline silicon layer 12 is removed, and the remaining polycrystalline silicon layer 12 is separated by fifth grooves 1212 to form fourth spacing units 1211. The third spacing group 54 used as the mask layer is removed. As shown in FIG. 15, the fifth groove 1212 is located between two adjacent fourth spacing units 1211, the sidewall surface of the fourth spacing unit 1211 coincides with the sidewall surface of the fifth groove 1212, and the sidewall surface of the fourth spacing unit 1211 is perpendicular to the surface of the oxide layer 11. The position corresponding to the fifth groove 1212 exposes a part of the surface of the oxide layer 11. Therefore, a pattern of the third spacing group 54 is transferred to the polycrystalline silicon layer 12 with high quality through the etching process, and both the final line width size and the trench size between lines of the fourth spacing unit 1211 formed in the polycrystalline silicon layer 12 are highly consistent.

An embodiment of the present disclosure further provides a semiconductor structure. Referring to FIG. 15, the semiconductor structure includes a substrate 10, an oxide layer 11 disposed on the substrate 10, and a polycrystalline silicon layer 12 disposed on the oxide layer 11. The polycrystalline silicon layer 12 includes multiple fourth spacing units 1211 disposed at intervals. There is a fifth groove 1212 between two adjacent fourth spacing units 1211, and the fifth groove 1212 exposes a part of the oxide layer 11.

The embodiments or implementations of this specification are described in a progressive manner, and each embodiment focuses on differences from other embodiments. The same or similar parts between the embodiments may refer to each other.

In the description of the specification, the description with reference to terms such as “an embodiment”, “an exemplary embodiment”, “some implementations”, “a schematic implementation” and “an example” means that the specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the accompanying drawings. These terms are merely intended to facilitate description of the present disclosure and simplify the description, rather than to indicate or imply that the mentioned apparatus or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one element from another.

The same elements in one or more accompanying drawings are denoted by similar reference numerals. For the sake of clarity, various parts in the accompanying drawings are not drawn to scale. In addition, some well-known parts may not be shown. For the sake of brevity, the structure obtained by implementing a plurality of steps may be shown in one figure. In order to make the understanding of the present disclosure more clearly, many specific details of the present disclosure, such as the structure, material, size, processing process, and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

In the method of manufacturing a semiconductor structure and the semiconductor structure provided in the embodiments of the present disclosure, only the mandrel layer is etched, which effectively reduces processing steps, reduces the impact of the etching process on a feature size of a transferred pattern, avoids the problem of pitch variation, and improves the processing efficiency while ensuring the processing effect.

1. A method of manufacturing a semiconductor structure, comprising:
providing an intermediate semiconductor structure, wherein the intermediate semiconductor structure comprises a substrate, and an oxide layer, a polycrystalline silicon layer, and a mandrel layer that are sequentially stacked on the substrate;
etching a part of the mandrel layer, exposing a part of the polycrystalline silicon layer, and forming a first spacing group;
depositing a first spacing layer, and covering the first spacing group and an exposed area of the polycrystalline silicon layer;
removing the first spacing group and a part of the first spacing layer, exposing a part of the polycrystalline silicon layer, and forming a second spacing group;
depositing a second spacing layer, and covering the second spacing group and an exposed area of the polycrystalline silicon layer;
removing the second spacing group and a part of the second spacing layer, exposing a part of the polycrystalline silicon layer, and forming a third spacing group; and
removing a part of the polycrystalline silicon layer and the third spacing group, and forming a fourth spacing group, wherein the fourth spacing group exposes a part of the oxide layer.

2. The method of manufacturing a semiconductor structure according to claim 1, wherein before etching the mandrel layer, the method further comprises:
forming a patterned photoresist layer on the mandrel layer, wherein the photoresist layer comprises multiple first grooves distributed at intervals, and the first grooves each expose a part of the mandrel layer.

3. The method of manufacturing a semiconductor structure according to claim 2, wherein the etching a part of the mandrel layer, exposing a part of the polycrystalline silicon layer, and forming a first spacing group comprises:
etching a part of the mandrel layer by using the photoresist layer as a mask layer, and forming a second groove, wherein the second groove exposes a first area of the polycrystalline silicon layer, and a reserved part of the mandrel layer forms the first spacing group;
wherein the first spacing group comprises multiple spaced first spacing units perpendicular to the polycrystalline silicon layer, and the second groove is formed between two adjacent first spacing units.

4. The method of manufacturing a semiconductor structure according to claim 3, wherein before the depositing a first spacing layer, the method further comprises:
removing the mask layer.

5. The method of manufacturing a semiconductor structure according to claim 3, wherein the depositing a first spacing layer, and covering the first spacing group and an exposed area of the polycrystalline silicon layer comprises:
depositing the first spacing layer through a physical vapor deposition process, wherein the first spacing layer covers a top surface and sidewall surfaces of each of the first spacing units and the first area of the polycrystalline silicon layer.

6. The method of manufacturing a semiconductor structure according to claim 5, wherein the removing the first spacing group and a part of the first spacing layer, exposing a part of the polycrystalline silicon layer, and forming a second spacing group comprises:
etching a part of the first spacing layer covering the top surface of each of the first spacing units;
etching a part of the first spacing layer covering the first area of the polycrystalline silicon layer; and
removing the first spacing group, wherein a reserved part of the first spacing layer forms the second spacing group;
wherein the second spacing group comprises multiple spaced second spacing units perpendicular to the polycrystalline silicon layer, two adjacent second spacing units form a third groove, and the third groove exposes a second area of the polycrystalline silicon layer.

7. The method of manufacturing a semiconductor structure according to claim 6, wherein a width of a projected profile of the first spacing unit on the substrate is greater than a width of a projected profile of the second spacing unit on the substrate.

8. The method of manufacturing a semiconductor structure according to claim 6, wherein a number of the second spacing units is twice a number of the first spacing units.

9. The method of manufacturing a semiconductor structure according to claim 6, wherein the depositing a second spacing layer, and covering the second spacing group and an exposed area of the polycrystalline silicon layer comprises:
depositing the second spacing layer through an atomic layer deposition process, wherein the second spacing layer covers a top surface and sidewall surfaces of each of the second spacing units and the second area of the polycrystalline silicon layer.

10. The method of manufacturing a semiconductor structure according to claim 9, wherein the removing the second spacing group and a part of the second spacing layer, exposing a part of the polycrystalline silicon layer, and forming a third spacing group comprises:
etching a part of the second spacing layer covering the top surface of each of the second spacing units;
etching a part of the second spacing layer covering the second area of the polycrystalline silicon layer; and
removing the second spacing group, wherein a reserved part of the second spacing layer forms the third spacing group;
wherein the third spacing group comprises multiple spaced third spacing units perpendicular to the polycrystalline silicon layer, two adjacent third spacing units form a fourth groove, and the fourth groove exposes a third area of the polycrystalline silicon layer.

11. The method of manufacturing a semiconductor structure according to claim 10, wherein a number of the third spacing units is quadruple a number of the first spacing units.

12. The method of manufacturing a semiconductor structure according to claim 10, wherein the removing a part of the polycrystalline silicon layer and the third spacing group, and forming a fourth spacing group, wherein the fourth spacing group exposes a part of the oxide layer comprises:
etching the third area of the polycrystalline silicon layer, and forming a fifth groove, wherein a reserved part of the polycrystalline silicon layer forms the fourth spacing group; and
removing the third spacing group;
wherein the fourth spacing group comprises multiple spaced fourth spacing units perpendicular to the oxide layer, two adjacent fourth spacing units form the fifth groove, and the fifth groove exposes a part of the oxide layer.

13. The method of manufacturing a semiconductor structure according to claim 1, wherein the mandrel layer comprises a silicon oxynitride layer and a spin-on-hardmask layer that are stacked.

14. The method of manufacturing a semiconductor structure according to claim 1, wherein a material of the first spacing layer is the same as or different from a material of the second spacing layer.

15. The method of manufacturing a semiconductor structure according to claim 14, wherein
the material of the first spacing layer comprises titanium nitride.

16. A semiconductor structure, wherein the semiconductor structure comprises:
a substrate;
an oxide layer, disposed on the substrate; and
a polycrystalline silicon layer, disposed on the oxide layer, wherein the polycrystalline silicon layer comprises multiple spacing units disposed at intervals, two adjacent spacing units form a groove, and the groove exposes a part of the oxide layer; wherein
the polycrystalline silicon layer is processed by using the method of manufacturing a semiconductor structure according to claim 1.
